(19) United States
(12) Patent Application Publication
(10) Pub. No.: US 2020/0149936 A1
(43) Pub. Date: May 14, 2020

(54) EVENT LOGGING

(71) Applicant: Andium Inc., New York, NY (US)

(72) Inventors: Rongkai Xu, Holmdel, NJ (US); Jory Schwach, New York, NY (US); Matt Ball, Colchester (GB)

(21) Appl. No.: 16/617,246

(22) PCT Filed: May 29, 2018
(86) PCT No.: PCT/US2018/034891

§ 371 Date: Nov. 26, 2019

Related U.S. Application Data
(60) Provisional application No. 62/512,167, filed on May 29, 2017.

(51) Int. Cl. G01F 1/34; E21B 47/00; H04Q 9/02; G01M 3/26; G01F 23/296; G01H 1/00; G01R 33/02

(52) U.S. Cl. CPC G01F 1/34; E21B 47/00; H04Q 9/02; G01M 3/26; H04Q 2209/10; G01H 1/00; G01R 33/02; H04Q 2209/40; H04Q 2209/70; G01F 23/296

(57) ABSTRACT

Various embodiments of the present disclosure include a method for event logging. The method can include receiving a first sensor signal from a first sensor via a first sensor transmitter, wherein the sensor signal is associated with a flow of oil out of an oil storage tank. The method can include receiving a second sensor signal from a second sensor via a second sensor transmitter, wherein the second sensor signal is associated with an air pump that pumps air into the oil storage tank. The method can include determining whether a leak exists in the oil tank, based on a lag between a time when the second sensor senses operation of the air pump and a time when the flow meter detects a flow of oil out of the outlet pipe.

### BACKGROUND

Applications, which include instructions that are executable by some type of computing device are prevalent in everyday life. Applications can be associated with consumer devices, industrial devices, etc. Many applications can record errors or events in logs. Some of these applications can have different formats and/or different user interfaces. Data provided from different applications cannot always be merged to produce a single report, thus requiring administrators to assemble desired information from a variety of sources. Analysis of the data can be time consuming and often times analysis of the data can be delayed.

### SUMMARY

Various embodiments of the present disclosure include a system for event logging. The system can include a sensor, wherein the sensor is configured to monitor a device associated with an oil well. The system can include a sensor transmitter in communication with the sensor. The system can include a central computer in communication with the sensor transmitter via a central computer transmitter, wherein the central computer includes a processor and memory storing non-transitory computer executable instructions. The instructions can be executed by the processor to receive a sensor signal from the sensor via the sensor transmitter, wherein the sensor signal is associated with a level of oil in an oil storage tank. The instructions can be executed by the processor to prioritize data associated with the sensor signal based on the level of oil in the oil storage tank. The instructions can be executed by the processor to create a priority queue that includes the data associated with the sensor signal and additional data associated with additional sensor signals received by the central computer from additional sensors. The instructions can be executed by the processor to generate a request for processing based on a priority of the data associated with the sensor signal in relation to the additional data.

Various embodiments of the present disclosure include a system for event logging. The system can include a sensor, wherein the sensor is configured to monitor a device associated with an oil well. The system can include a remote terminal unit that interfaces a sensor transmitter with the sensor. The system can include a central computer in communication with the sensor transmitter via a central computer transmitter, wherein the central computer includes a processor and memory storing non-transitory computer executable instructions. The instructions can be executed by the processor to receive a sensor signal from the sensor via the sensor transmitter, wherein the sensor signal is associated with a level of oil in an oil storage tank. The instructions can be executed by the processor to prioritize data associated with the sensor signal based on the level of oil in the oil storage tank. The instructions can be executed by the processor to create a priority queue that includes the data associated with the sensor signal and additional data associated with additional sensor signals received by the central computer from additional sensors. The instructions can be executed by the processor to generate a request for processing based on a priority of the data associated with the sensor signal in relation to the additional data.

Various embodiments of the present disclosure include a method for event logging. The method can include receiving a first sensor signal from a first sensor via a first sensor transmitter, wherein the sensor signal is associated with a flow of oil out of an oil storage tank. The method can include receiving a second sensor signal from a second sensor via a second sensor transmitter, wherein the second sensor signal is associated with an air pump that pumps air into the oil storage tank. The method can include determining whether a leak exists in the oil tank, based on a lag between a time when the second sensor senses operation of the air pump and a time when the flow meter detects a flow of oil out of the outlet pipe.

### BRIEF DESCRIPTION OF DRAWINGS

FIG. 1A depicts a system that includes a number of devices and associated sensors that are in communication with a central computer, in accordance with embodiments of the present disclosure.

FIG. 1B depicts a system that includes a number of devices and associated sensors coupled with respective remote terminal units (RTUs) that are in communication with a central computer, in accordance with embodiments of the present disclosure.

FIG. 2 depicts a graph illustrating time versus a level of fullness of a tank, in accordance with various embodiments of the present disclosure.

FIG. 3 depicts a high priority set of data and a low priority set of data and a priority queue that can be used to process data, in accordance with embodiments of the present disclosure.

FIG. 4 depicts a graph showing sensor readings associated with an indirect triggering event, in accordance with various embodiments of the present disclosure.

FIG. 5 depicts a diagram of an example of a computing device, in accordance with various embodiments of the present disclosure.

### DETAILED DESCRIPTION

Embodiments of the present disclosure are described below with reference to the accompanying figures. The features and advantages which are explained are illustrated by way of example and not by way of limitation. One of ordinary skill in the art will recognize that there are additional features and advantages provided by embodiments of the present disclosure beyond those described herein.

With the proliferation of the Internet of Things (IoT), there are many novel applications, which have never existed before, but have now become a real possibility. Based on large real-time data volume feeding into the cloud, there are certain requirements for the cloud platform to perform near real-time data processing, analytics, and machine learning. In some embodiments, the IoT can have a large impact on consumer applications, industrial applications, etc. One particular example of an industrial application on which IoT can have a large impact on can be the oil and gas industry. For example, millions of wells exist across North America and the world, which generate billions of barrels of oil annually. Much of the technology and equipment associated with these wells is largely antiquated. For example, sensors that monitor characteristics of produced oil and gas from the wells and/or monitor characteristics associated with storage tanks that store the produced oil can be antiquated. Additionally, devices that control the flow of oil and gas to and/or from the well and/or storage tanks can also be antiquated. Furthermore, many of the sensors and/or devices may not be centrally linked to a central computer in an efficient way.

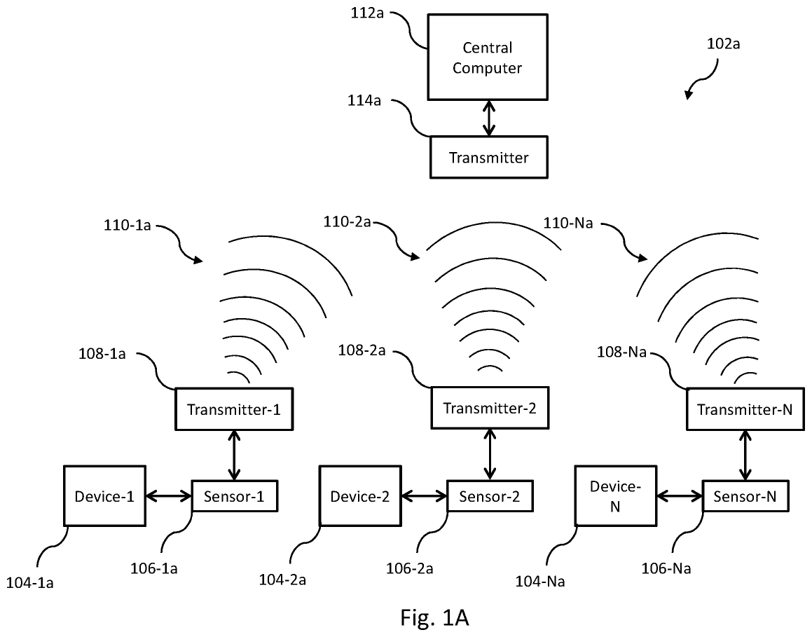

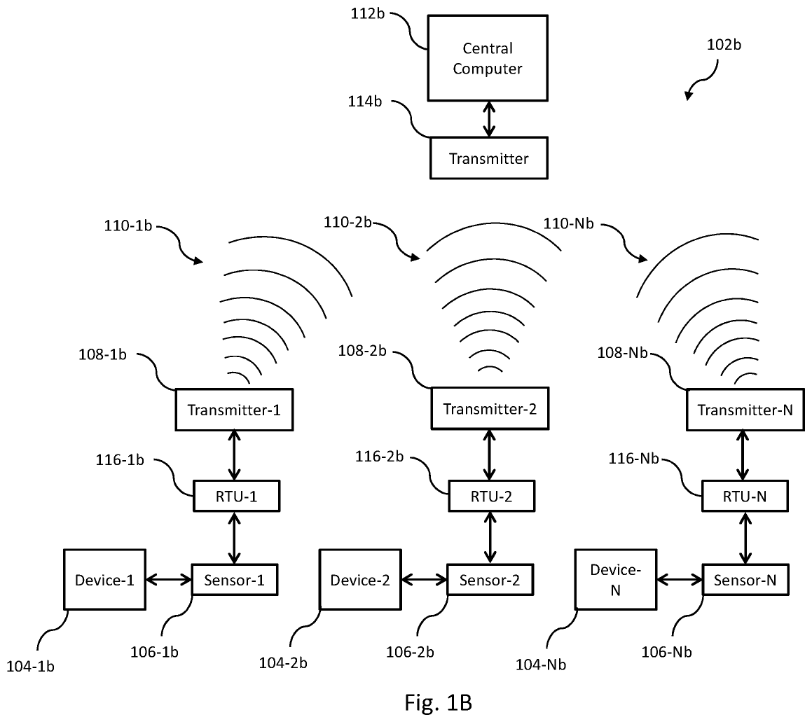

FIG. 1A depicts a system 102a that includes a number of devices 104-1a, 104-2a, . . . , 104-Na and associated sensors 106-1a, 106-2a, . . . , 106-Na that are in communication with a central computer 112a, in accordance with embodiments of the present disclosure. In an example, the devices 104-1a, 104-2a, . . . , 104-Na can be static and/or dynamic, mechanical and/or electrical, and can be consumer devices, industrial devices, etc. In a particular embodiment, the devices 104-1a, 104-2a, . . . , 104-Na can be equipment associated with an oil well. Although an oil well is given in examples in relation to FIG. 1 and the figures throughout, embodiments of the present disclosure apply equally to a gas well and associated equipment therewith (e.g., gas storage tanks, gas pipelines, etc.). For example, the devices 104-1a, 104-2a, . . . , 104-Na can be storage tanks associated with an oil well, which can be configured for the collection and/or storage of petroleum oil. However, the devices 104-1a, 104-2a, . . . , 104-Na can be other types of devices, as discussed herein. In some embodiments, the devices 104-1a, 104-2a, . . . , 104-Na can be a well head, pipe line, electric motor, compressor, generator, pump, among other types of devices.

In some embodiments, the sensors 106-1a, 106-2a, . . . , 106-Na can be configured to monitor one or more characteristics of a respective one of the devices 104-1a, 104-2a, . . . , 104-Na. For example, where the device is a storage tank associated with the oil well, the sensor 106-1a, 106-2a, . . . , 106-Na can monitor a level of fluid (e.g., petroleum) in the tank. Such a sensor can be an ultrasonic sensor, in some embodiments, which can be desired because the sensor can be completely contained, reducing a risk of spark, explosion, fire, etc. However, the sensor can be another type of sensor configured to monitor the level of fluid in the tank and/or measure another characteristic associated with the tank. In some embodiments, the sensor can make measurements associated with the level of fluid in the tank at defined intervals. For instance, the sensor can make measurements associated with the level of fluid in the tank at 1 second intervals, 5 second intervals, 20 second intervals, 1 minute intervals, etc.

In some embodiments, based on a signal produced by the sensor, a level of fluid in the storage tank can be determined. In some embodiments, the sensors can be in communication with a central computer 112a via a communication link. In some embodiments, the communication link can be a wired and/or wireless communication link. As depicted in FIG. 1A, the communication link is wireless. For example, each one of the sensors 106-1a, 106-2a, . . . , 106-Na can be coupled with a respective transmitter 108-1a, 108-2a, . . . , 108-Na (e.g., sensor transmitter). In an example, a two way communication link can be established between the transmitters 108-1a, 108-2a, . . . , 108-Na and the respective sensors 106-1a, 106-2a, . . . , 106-Na, such that data can be transferred from each one of the sensors 106-1a, 106-2a, . . . , 106-Na and/or data can be transferred to each one of the sensors 106-1a, 106-2a, . . . , 106-Na. In some embodiments, where the communication link between each one of the sensors 106-1a, 106-2a, . . . , 106-N and the central computer 112a is wireless, the transmitters 108-1a, 108-2a, . . . , 108-Na in communication with each one of the sensors 106-1a, 106-2a, . . . , 106-Na and a central computer transmitter 114a (e.g., central computer transmitter) in two-way communication with the central computer 112a can wirelessly send and/or receive data from one another. For example, as depicted, wireless signals 110-1a, 110-2a, . . . , 110-Na can be transmitted from the transmitters 108-1a, 108-2a, . . . , 108-Na and can be received by the central computer transmitter 114a. In some embodiments, although not depicted, wireless signals 110-1a, 110-2a, . . . , 110-Na can be transmitted from the central computer transmitter 114a and can be received by the transmitters 108-1a, 108-2a, . . . , 108-Na.

FIG. 1B depicts a system 102b that includes a number of devices 104-1b, 104-2b, . . . , 104-Nb and associated sensors 106-1b, 106-2b, . . . , 106-Nb coupled with respective remote terminal units (RTUs) 116-1b, 116-2b, . . . , 116-Nb that are in communication with a central computer 112b, in accordance with embodiments of the present disclosure. The system 102b includes the same or similar elements as those depicted and described in relation to FIG. 1A, with the addition of RTUs 116-1b, 116-2b, . . . , 116-Nb. In an example, the devices 104-1b, 104-2b, . . . , 104-Nb can be static and/or dynamic, mechanical and/or electrical, and can be consumer devices, industrial devices, etc. In a particular embodiment, the devices 104-1b, 104-2b, . . . , 104-Nb can be equipment associated with an oil well. For example, the devices 104-1b, 104-2b, . . . , 104-Nb can be storage tanks associated with an oil well, which can be configured for the collection and/or storage of petroleum oil.

In some embodiments, the sensors 106-1b, 106-2b, . . . , 106-Nb can be configured to monitor one or more characteristics of a respective one of the devices 104-1b, 104-2b, . . . , 104-Nb. For example, where the device is a storage tank associated with the oil well, the sensor 106-1b, 106-2b, . . . , 106-Nb can monitor a level of fluid (e.g., petroleum) in the tank.

Each one of the sensors 106-1b, 106-2b, . . . , 106-Nb can be coupled with a respective transmitter 108-1b, 108-2b, . . . , 108-Nb. In an example, a two way communication link can be established between the transmitters 108-1b, 108-2b, . . . , 108-Nb and the respective sensors 106-1b, 106-2b, . . . , 106-Nb, such that data can be transferred from each one of the sensors 106-1b, 106-2b, . . . , 106-Nb and/or data can be transferred to each one of the sensors 106-1b, 106-2b, . . . , 106-Nb. In some embodiments, where the communication link between each one of the sensors 106-1b, 106-2b, . . . , 106-Nb and the central computer 112b is wireless, the transmitters 108-1b, 108-2b, . . . , 108-Nb in communication with each one of the sensors 106-1b, 106-2b, . . . , 106-Nb and a central computer transmitter 114b in two-way communication with the central computer 112b can wirelessly send and/or receive data from one another. For example, as depicted, wireless signals 110-1b, 110-2b, . . . , 110-Nb can be transmitted from the transmitters 108-1b, 108-2b, . . . , 108-Nb and can be received by the central computer transmitter 114b. In some embodiments, wireless signals 110-1b, 110-2b, . . . , 110-Nb can be transmitted from the central computer transmitter 114b and can be received by the transmitters 108-1b, 108-2b, . . . , 108-Nb.

In some embodiments, the RTUs 116-1b, 116-2b, . . . , 116-Nb can be microprocessor-controlled electronic devices that interface the sensors 106-1b, 106-2b, . . . , 106-Nb with the transmitters 108-1b, 108-2b, 108-Nb and the central computer 112b, which in some embodiments can be a distributed control system, supervisory control and data acquisition system, etc. In some embodiments, data received from the sensors 106-1b, 106-2b, 106-Nb can be processed and/or analyzed via the RTUs, before the data is communicated to the central computer 112b.

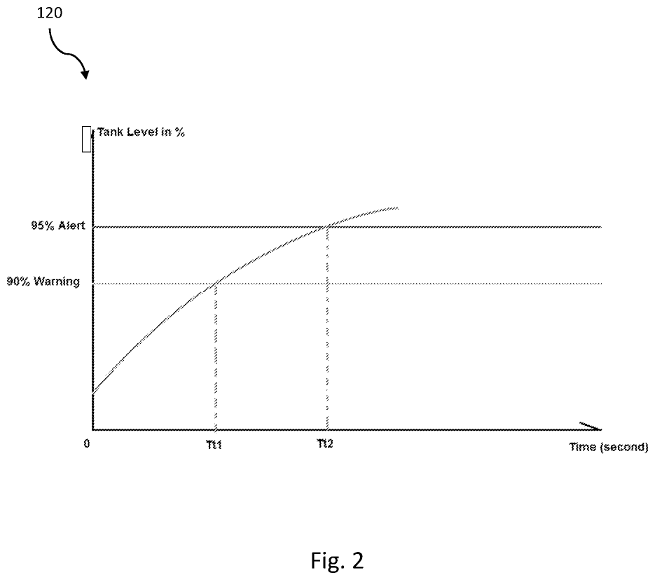

FIG. 2 depicts a graph 120 illustrating time versus a level of fullness of a tank, in accordance with various embodiments of the present disclosure. In an example, time can be represented on the x-axis, as depicted, and the level of fullness of the tank can be represented on the y-axis of the graph 120. As depicted, the graph 120 shows a tank level in percentage of fullness of the tank varying with time. At time Tt1, a tank level sensor can trigger a first defined warning. In the example, the first defined warning can be triggered when the tank level is 90 percent full, although the first defined (e.g., predefined) warning can be triggered at other levels of fullness. At time Tt2, a second defined warning can be triggered. In an example, the second defined warning can be triggered when the tank level is 95 percent full, although the second defined warning can be triggered at other levels of fullness. Additionally, although two defined warnings are discussed, fewer than or greater than two defined warnings can be implemented (e.g., 1, 3, 6 defined warnings). In some embodiments, in response to the warnings, the well associated with an oil tank can be shut down. For example, a message can be received via a transmitter in communication with a computing device associated with the well. The message can be received via a centralized communications center, in some embodiments. In some embodiments, instructions can be executed by the computing device to shut down the well when the warning or alert is generated. For example, one or more pumps and/or one or more valves can be shut down or closed in response to the message received via the centralized communications center.

In the above example, two tier event triggering processing routines can be used to process the data associated with each defined warning. In some embodiments of the present disclosure, the data associated with the first defined warning and the data associated with the second defined warning can be given different priority in terms of how the data is processed (e.g., communicated to other devices, modified, etc.). Some embodiments of the present disclosure can include analyzing the data to determine a priority level associated with the data. For example, the data can be analyzed to determine what level of fullness of the tank, or some other characteristic with which the data is associated. Based on this analysis, the data can be processed differently, as discussed herein.

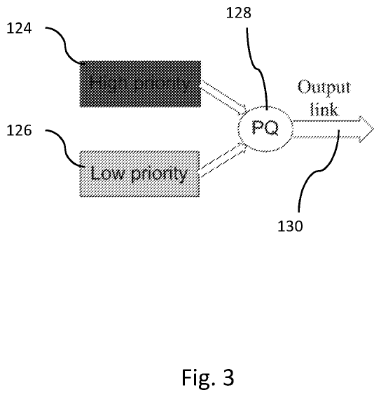

FIG. 3 depicts a high priority set of data 124 and a low priority set of data 126 and a priority queue 128 that can be used to process data 124, 126, in accordance with embodiments of the present disclosure. As depicted, the high priority data 124 and the low priority data 126 can be fed through the priority queue, based on the priority of the data. In some embodiments, the data 124, 126 can be data associated with a level of fullness of a tank (e.g., oil storage tank), as discussed herein. In an example, the high priority data 124 can be associated with a level of fullness that is greater than the low priority data 126. For instance, the high priority data 124 can be associated with a level of fullness of the tank that is 95 percent full and the low priority data 126 can be associated with a level of fullness of the tank that is 90 percent full.

In some embodiments, the data 124, 126 can be placed in the priority queue, based on a determination of the priority of the data 124, 126, the determined priority of the data 124, 126 being based on the analysis of the data. For instance, in an example where the priority of the data is associated with the level of fullness of an oil storage tank, a low priority can be given to data associated with the level of fullness of the tank that is 90 percent full and a high priority, relative to the low priority, can be given to data associated with the level of fullness of the tank that is 95 percent full. Accordingly, the level of priority of the data 124, 126 can be considered when processing the data in the priority queue 128. In some embodiments, the high priority data 124 can be given a higher priority because the oil storage tank is closer to reaching its maximum storage capacity (e.g., is 95 percent full). Accordingly, it is important that the oil storage tank be serviced sooner than oil storage tanks that are less full (e.g., 90 percent full). Upon being processed via the priority queue, the data 124, 126 can be sent via an output link, which can be a wired and/or wireless communication channel that is connected with a computer (e.g., RTU, central computer). In an example, a request for processing can be sent via the output link to a technician to offload oil from the oil storage tank. For instance, a real-time warning can be sent to technicians for acting on, after the above threshold is met. In some embodiments, a request for processing can be sent directly to the oil storage tank and can include computer executable instructions, which can be executed by an RTU associated with the oil tank to stop pumping oil into the oil storage tank.

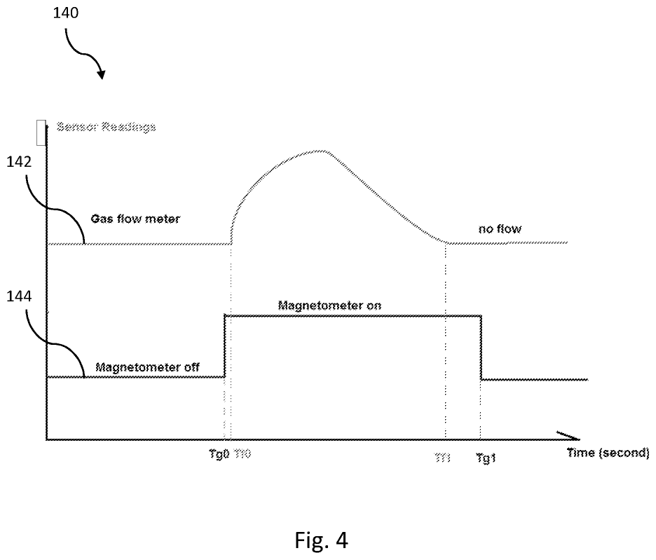

FIG. 4 depicts a graph 140 showing sensor readings associated with an indirect triggering event, in accordance with various embodiments of the present disclosure. As depicted, the sensor reading is depicted on the y-axis and time is depicted on the x-axis. As further depicted, the sensor readings can be associated with a gas flow meter, which is represented by gas flow meter line 142 and a magnetometer, which is represented by magnetometer line 144. In some embodiments, the magnetometer can be one such as that discussed in relation to PCT application no. PCT/US2017/053860, which is incorporated by reference as though fully set forth herein. Previously, some sensors that were employed to monitor second-by-second data associated with oil and/or gas storage tanks (e.g., activation of oil transfer pumps, gas flow meters, etc.) measured data at relatively large time intervals. These time intervals can make it difficult to accurately determine characteristics associated with the oil and/or gas storage tanks. Additionally, the operation of some equipment associated with oil storage tanks was not measured at all. For example, operation of a pump, which pumps air into the oil storage tank, creating a positive pressure and thus forcing oil out of the tank was not monitored and/or was not monitored at a high enough frequency for the data to be useful. Embodiments of the present disclosure can include receiving data from a magnetometer, or other type of sensor as discussed herein, that is placed in proximity to the pump and monitors the electromagnetic field upon activation of the pump. In some embodiments, a magnetometer, or other type of sensor as discussed herein, can be placed in proximity to a generator that creates electricity that drives the pump. Thus, the magnetometer or other type of sensor can detect when the pump and/or generator is running. Specifically, the magnetometer or other type of sensor can detect when the pump and/or generator is running with much more granularity than was previously possible in such applications.

In some embodiments, FIG. 4 can depict a real-time oil and/or gas leak detection. In an example, an oil and/or gas pump can be used to pump oil and/or gas from an oil and/or gas storage tank to downstream storage and/or transmission units. At normal operation, whenever the oil and/or gas pump starts pumping, the oil and/or gas flow meter can start to sense a differential pressure and flow change. However, if there was a leakage between the pump and downstream flow measuring devices, then there can be some timing misalignment between a start and/or stop of the pump and measured real-time oil and/or gas flow. The time different can be represented as Tf0-Tg0, and Tg1-Tf1. The difference in time exists, the more leakage can be indicated. Thus, the RTU and priority queue mentioned previously can be used to safely shut down a flow of oil and/or gas in a pipe and/or alert a technician to prevent a potential disaster.

As discussed, in some embodiments, the magnetometer can be disposed on a generator that powers the pump. Alternatively, embodiments of the present disclosure can employ sensors other than magnetometers. For example, a sensor that measures vibration can be disposed on the pump and/or generator. As the pump and/or generator is activated, the pump and/or generator can produce vibrations. In some embodiments of the present disclosure that utilize a vibration sensor, a filter can be employed to only recognize those vibrations with a frequency associated with the pump and/or generator. For example, the filter can prevent the sensor from collecting data from vibrations that are produced by vibration anomalies that are not associated with the pump and/or generator. In some embodiments, the sensor may collect data, however, the data may be filtered via the filter to reduce and/or eliminate signals that have been collected by the sensor. This can prevent a false signal that indicates that the pump and/or generator is running. In some embodiments, the sensor can be a Hall Effect sensor. In some embodiments, instead of a magnetometer or vibration sensor, another type of sensor that can be used to measure an air flow into the tank can be an air flow meter, which can be connected to an airline connected to the tank.

As depicted in relation to FIG. 4, a magnetic flux, represented by the magnetometer line 144 (or other value being measured by the magnetometer) can increase at time Tg0, indicating that the pump associated with the oil storage tank has turned on and is pumping air into the oil storage tank in order to generate a positive pressure in the tank, causing the oil in the oil storage tank to flow out of the tank. As discussed above, a vibration signal produced by a pump, for example, can be measured and can have a similar or same profile as the magnetometer line 144. As further depicted, at time Tf0, oil begins to flow out of the tank as pressure in the tank builds. In some embodiments, the data associated with the magnetometer (or other sensor) can be measured in 20 second intervals and the data associated with the gas flow meter can be measured in 1 second intervals, thus creating a feedback loop, although the data associated with the magnetometer and the gas flow meter can be measured at greater time intervals or lesser time intervals. In an example, the magnetometer (or other sensor) data can be measured in intervals from 1 second to 1 minute, 5 seconds to 45 seconds, 10 seconds to 30 seconds, and/or 15 seconds to 25 seconds. All individual values and subranges from and including 1 second to 1 minute are included herein and disclosed herein. In some embodiments, the magnetometer (or other sensor) data can be measured in intervals of less than 1 second or greater than 1 minute. In an example, the flow meter (or other sensor) data can be measured in intervals from 0.1 second to 1 minute, 0.5 seconds to 45 seconds, 0.75 seconds to 30 seconds, and/or 1 second to 25 seconds. All individual values and subranges from and including 0.1 second to 1 minute are included herein and disclosed herein. In some embodiments, the flow meter (or other sensor) data can be measured in intervals of less than 0.1 second or greater than 1 minute.

Previously, a feedback loop between the gas flow meter and the pump did not exist and further the data was not measured with enough granularity to effectively create a feedback loop. Because a time at which the pump is activated can be measured with an increased granularity through analysis of the signal produced by the magnetometer, a determination can be made in relation to the signal from the gas flow meter and the magnetometer to determine if a leak exists in the tank. For instance, because the pump starts pumping at Tg0 and the gas flow meter does not start measuring a flow of gas until Tf0, a determination can be made that an air leak exists in the oil storage tank (e.g., due to the lag between the start of the pumping of air and the flow of gas).

Additionally, at time Tf1, a signal produced by the gas flow meter can indicate that the flow of gas out of the tank has stopped. However, the signal produced by the magnetometer indicates that the pump does not stop pumping until Tg1, a time later than Tf1. Accordingly, this can indicate that a leak exists in the oil storage tank. For instance, because the pump does not stop pumping until Tg1 and the gas flow meter stops measuring a flow of gas at Tf1, a determination can be made that an air leak exists in the oil storage tank (e.g., due to the lag between the end of the pumping of air and the premature ending of the flow of gas).

Previously, the technology associated with oil storage tanks did not allow and/or was not configured to allow for data to be received from equipment associated with the oil storage tank at a high enough sampling rate to enable a determination of an operational status (e.g., an air leak) associated with the oil storage tank. In some embodiments, when a computer and/or cloud computing system determines that a time difference between the data received from the gas flow meter and the magnetometer is large enough, then an alert can be issued that the air leak exists. This is an indirect trigger to the system. In some embodiments, the trigger can purely be based on machine learning and intelligent algorithms.

In some embodiments, at warning level, the computer and/or cloud computing system can process the information and enter into the warning mode to give some warning information to the end user, while letting the streaming data flow through a circular buffer. However, at alert level, the computer and/or cloud system may not only alert the system and end user, but can also log a previous time period (e.g., 60 seconds) worth of data for diagnostic purposes. That operation can save the circular buffer data to an event trigger file, which could be retrieved at a later time. In some embodiments, at warning level, the system can also log data for diagnostic purposes over some period of time (e.g., 60 seconds). In some embodiments the warning level can be triggered by a threshold value (e.g., level of tank) that is lower than a threshold value that can trigger the alert level.

Although some embodiments discussed herein relate to applications in the oil and gas filed, embodiments of the present disclosure can be used in other fields as well. For example, embodiments of the present disclosure can be used in smart grid applications. In some embodiments, characteristics associated with an electrical grid can be monitored and reported via embodiments of the present disclosure. In such an embodiment, there are government regulations on when and how the triggered events are to be logged. In monitoring an electrical grid, a size of the circular buffer can be increased, event triggering timing can be changed, and a triggering method can be changed.

In some embodiments of the present disclosure pre-triggering events can be saved. For example, when an event associated with the oil storage tank occurs, data collected from the magnetometer, the gas flow meter, and/or other sensors associated with the oil storage tank, oil well, and/or a portion of the oil storage tank and well system can be saved. This data can be further analyzed to determine characteristics associated with the triggering event and operation of the oil tank and/or system associated with the oil tank.

In some embodiments, the pump can be powered by a generator. In some embodiments, the generator can be turned on, creating electrical power that drives the pump. In some embodiments, the magnetometer can be disposed on the generator. As such, when the generator is activated, assuming there are no electrical problems with the pump, then the pump can be activated and oil can be pumped out of the oil storage tank and can be measured by the gas flow meter. However, in some embodiments of the present disclosure, the pump may not be operational. As such, when the generator is turned on, the pump does not pump air. As discussed herein, the gas flow meter can also collect data and can be compared with the operation of the pump. Accordingly, a determination can be made based on the comparison of the data from the gas flow meter and the pump that the pump is not functional. In some embodiments, an indication and/or warning that the pump is not functioning can be generated and communicated to a computer and/or cloud computing system.

Some embodiments of the present disclosure can measure other characteristics associated with an oil well, oil storage tank, and/or components associated therewith. For instance, some embodiments of the present disclosure can measure characteristics of the oil well at the well head and/or other portions of the well. In an example, a pressure and/or flow of the well can be measured with a sensor disposed in communication with the well (e.g., at the well head). In some embodiments, a pressure associated with a portion of the well can be determined and/or a flow of oil through a portion of the well can be determined based on data received from the sensors. In some embodiments, sensors and/or meters as discussed herein can measure data in real time. Additionally, the data can be communicated in real time to a central communications center, computer, cloud computing system, etc. In some embodiments, the sensors can take data points at a greater frequency than currently available. For instance, the sensors can measure data at fractions of a second, a second, three seconds, twenty seconds, thirty seconds, one minute, two minutes, etc.

In some embodiments, a well can be characterized based on data received from the sensors disposed within a portion of the well. For example, a decay of the well can be determined based on readings obtained from pressure sensors and/or flow meters disposed within the portion of the well. The characterization of the well can be associated with whether a production of the well is increasing and/or decreasing, based on the flow and/or the pressure. In some embodiments, the decay of the well can be tracked over a period of time. For example, data associated with the decay of the well can be recorded and analyzed.

In some embodiments, a pressure increase and/or decrease associated with the well can be detected via a pressure sensor in communication with the well. This information and/or the other characteristics associated with the well discussed herein can be communicated to a computer and/or a cloud computing system. The data associated with the well characteristics discussed herein can be measured at a higher frequency, allowing for characteristics associated with the well to be accurately measured. In some embodiments, the pressure increase and/or decrease associated with the well can be used in the determination of the decay of the well.

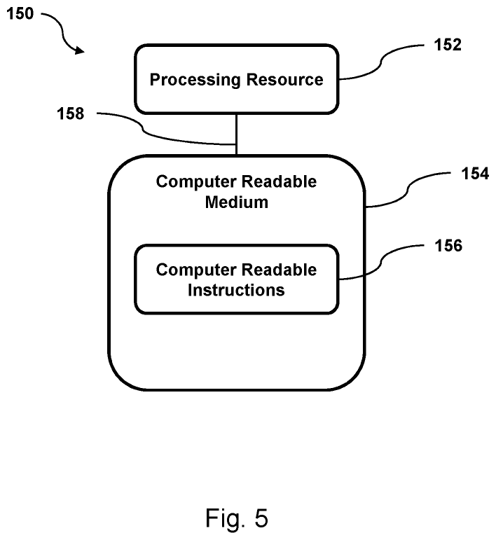

FIG. 5 depicts a diagram of an example of a computing device, in accordance with various embodiments of the present disclosure. The computing device 150 can utilize software, hardware, firmware, and/or logic to perform a number of functions described herein. In an example, the computing device 150 can be representative of the central computer 112a, 112b and/or RTUs 116-1a, 116-2a, 116-Na, 116-1b, 116-2b, 116-Nb.

The computing device 150 can be a combination of hardware and instructions 156 to share information. The hardware, for example can include a processing resource 152 and/or a memory resource 154 (e.g., computer-readable medium (CRM), database, etc.). A processing resource 152, as used herein, can include a number of processors capable of executing instructions 156 stored by the memory resource 154. Processing resource 152 can be integrated in a single device or distributed across multiple devices. The instructions 156 (e.g., computer-readable instructions (CRI)) can include instructions 156 stored on the memory resource 154 and executable by the processing resource 152 to implement a desired function (prioritize data associated with the sensor signal based on the level of oil in the oil storage tank, etc.).

The memory resource 154 can be in communication with the processing resource 152. The memory resource 154, as used herein, can include a number of memory components capable of storing instructions 156 that can be executed by the processing resource 152. Such memory resource 154 can be a non-transitory CRM. Memory resource 154 can be integrated in a single device or distributed across multiple devices. Further, memory resource 154 can be fully or partially integrated in the same device as processing resource 152 or it can be separate but accessible to that device and processing resource 152. Thus, it is noted that the computing device 150 can be implemented on a support device and/or a collection of support devices, on a mobile device and/or a collection of mobile devices, and/or a combination of the support devices and the mobile devices.

The memory resource 154 can be in communication with the processing resource 152 via a communication link 158 (e.g., path). The communication link 158 can be local or remote to a computing device associated with the processing resource 152. Examples of a local communication link 158 can include an electronic bus internal to a computing device where the memory resource 154 is one of a volatile, non-volatile, fixed, and/or removable storage medium in communication with the processing resource 152 via the electronic bus.

Link 158 (e.g., local, wide area, regional, or global network) represents a cable, wireless, fiber optic, or remote connection via a telecommunication link, an infrared link, a radio frequency link, and/or other connectors or systems that provide electronic communication. That is, the link 158 can, for example, include a link to an intranet, the Internet, or a combination of both, among other communication interfaces. The link 158 can also include intermediate proxies, for example, an intermediate proxy server (not shown), routers, switches, load balancers, and the like.

Embodiments are described herein of various apparatuses, systems and/or methods. Numerous specific details are set forth to provide a thorough understanding of the overall structure, function, manufacture, and use of the embodiments as described in the specification and illustrated in the accompanying drawings. It will be understood by those skilled in the art, however, that the embodiments may be practiced without such specific details. In other instances, well-known operations, components, and elements have not been described in detail so as not to obscure the embodiments described in this specification. Those of ordinary skill in the art will understand that the embodiments described and illustrated herein are non-limiting examples, and thus it can be appreciated that the specific structural and functional details disclosed herein may be representative and do not necessarily limit the scope of the embodiments.

Reference throughout the specification to “various embodiments”, “some embodiments”, “one embodiment”, or “an embodiment”, or the like, means that a particular feature, structure, or characteristic described in connection with the embodiment(s) is included in at least one embodiment. Thus, appearances of the phrases “in various embodiments”, “in some embodiments”, “in one embodiment”, or “in an embodiment”, or the like, in places throughout the specification, are not necessarily all referring to the same embodiment. Furthermore, the particular features, structures or characteristics may be combined in any suitable manner in one or more embodiments. Thus, the particular features, structures, or characteristics illustrated or described in connection with one embodiment may be combined, in whole or in part, with the features, structures, or characteristics of one or more other embodiments without limitation given that such combination is not illogical or non-functional.

What is claimed is:

1. A system for event logging, comprising:
a sensor, wherein the sensor is configured to monitor a device associated with an oil well;
a sensor transmitter in communication with the sensor;
a central computer in communication with the sensor transmitter via a central computer transmitter, wherein the central computer includes a processor and memory storing non-transitory computer executable instructions, executable by the processor to:
receive a sensor signal from the sensor via the sensor transmitter, wherein the sensor signal is associated with a level of oil in an oil storage tank;
prioritize data associated with the sensor signal based on the level of oil in the oil storage tank;
create a priority queue that includes the data associated with the sensor signal and additional data associated with additional sensor signals received by the central computer from additional sensors; and
generate a request for processing based on a priority of the data associated with the sensor signal in relation to the additional data.

2. The system of claim 1, wherein the request for processing includes an indication provided to a field technician to offload oil from the oil storage tank.

3. The system of claim 1, further comprising a remote terminal unit that includes a microprocessor, the remote terminal unit in communication with the sensor and the sensor transmitter, wherein the request for processing includes an instruction sent to the remote terminal unit and executed by the remote terminal unit to stop oil from flowing into the oil storage tank.

4. The system of claim 3, wherein the remote terminal unit interfaces the sensor, the sensor transmitters, and the central computer.

5. The system of claim 1, wherein a priority of the data associated with the sensor signal increases as the level of oil in the oil storage tank increases.

6. The system of claim 1, further comprising a device sensor, the device sensor configured to monitor a device associated with an oil well.

7. The system of claim 6, wherein the device associated with the oil well is selected from the group consisting of a well head, a pipe line, an electric motor, a compressor, a generator, and a pump.

8. The system of claim 1, wherein the instructions executable to generate a request for processing based on a priority of the data associated with the sensor signal in relation to the additional data include instructions to generate a request for processing of a first set of data associated with a first oil tank before a second set of data associated with a second oil tank, wherein a level of oil in the first oil tank is greater than a level of oil in the second oil tank.

9. The system of claim 8, wherein the request for processing includes instructions to shut down an oil well associated with the first oil tank.

10. The system of claim 1, wherein the sensor is an ultrasonic sensor configured to determine a level of oil in the oil storage tank.

11. The system of claim 1, further comprising a second and third sensor, wherein the third sensor is a flow meter that is configured to detect an oil flow out of the oil storage tank through an outlet pipe.

12. The system of claim 11, wherein the second sensor is configured to detect operation of an air pump that pumps air into the oil tank and includes at least one of a magnetometer and a vibration sensor.

13. The system of claim 12, further comprising instructions executable by the central computer to determine a whether a leak exists in the oil tank, based on a lag between a time when the magnetometer senses operation of the air pump and a time when the flow meter detects a flow of oil out of the outlet pipe.

14. A system for event logging, comprising:
a sensor, wherein the sensor is configured to monitor a device associated with an oil well;
a remote terminal unit that interfaces a sensor transmitter with the sensor;
a central computer in communication with the sensor transmitter via a central computer transmitter, wherein the central computer includes a processor and memory storing non-transitory computer executable instructions, executable by the processor to:
receive a sensor signal from the sensor via the sensor transmitter, wherein the sensor signal is associated with a level of oil in an oil storage tank;
prioritize data associated with the sensor signal based on the level of oil in the oil storage tank;
create a priority queue that includes the data associated with the sensor signal and additional data associated with additional sensor signals received by the central computer from additional sensors; and
generate a request for processing based on a priority of the data associated with the sensor signal in relation to the additional data.

15. The system of claim 14, wherein the request for processing includes an indication provided to a field technician to offload oil from the oil storage tank.

16. The system of claim 14, wherein the remote terminal unit includes a microprocessor, the remote terminal unit in communication with the sensor and the sensor transmitter, wherein the request for processing includes an instruction sent to the remote terminal unit and executed by the remote terminal unit to stop oil from flowing into the oil storage tank.

17. The system of claim 16, wherein the remote terminal unit interfaces the sensor, the sensor transmitters, and the central computer.

18. The system of claim 14, wherein a priority of the data associated with the sensor signal increases as the level of oil in the oil storage tank increases.

19. The system of claim 14, further comprising a device sensor, the device sensor configured to monitor a device associated with an oil well.

20. The system of claim 19, wherein the device associated with the oil well is selected from the group consisting of a well head, a pipe line, an electric motor, a compressor, a generator, and a pump.

21. The system of claim 14, wherein the instructions executable to generate a request for processing based on a priority of the data associated with the sensor signal in relation to the additional data include instructions to generate a request for processing of a first set of data associated with a first oil tank before a second set of data associated with a second oil tank, wherein a level of oil in the first oil tank is greater than a level of oil in the second oil tank.

22. The system of claim 2, wherein the request for processing includes instructions to shut down an oil well associated with the first oil tank.

23. The system of claim 24, wherein the sensor is an ultrasonic sensor configured to determine a level of oil in the oil storage tank.

24. The system of claim 14, further comprising a second and third sensor, wherein the third sensor is a flow meter that is configured to detect an oil flow out of the oil storage tank through an outlet pipe.

25. The system of claim 24, wherein the second sensor is configured to detect operation of an air pump that pumps air into the oil tank and includes at least one of a magnetometer and a vibration sensor.

26. The system of claim 25, further comprising instructions executable by the central computer to determine a whether a leak exists in the oil tank, based on a lag between a time when the magnetometer senses operation of the air pump and a time when the flow meter detects a flow of oil out of the outlet pipe.

27. A method for event monitoring, comprising:
receiving a first sensor signal from a first sensor via a first sensor transmitter, wherein the sensor signal is associated with a flow of oil out of an oil storage tank;
receiving a second sensor signal from a second sensor via a second sensor transmitter, wherein the second sensor signal is associated with an air pump that pumps air into the oil storage tank;
determining whether a leak exists in the oil tank, based on a lag between a time when the second sensor senses operation of the air pump and a time when the flow meter detects a flow of oil out of the outlet pipe.

28. The method of claim 27, wherein the second sensor is a magnetometer that measures a magnetic flux produced by the air pump.

29. The method of claim 27, wherein the second sensor is a vibration sensor that measures a vibration produced by the air pump.

30. The method of claim 27, further comprising sampling the first signal from the first sensor in an interval in a range from 0.1 seconds to 1 minute.

31. The method of claim 27, further comprising sampling the second signal from the second sensor in an interval in a range from 1 second to 1 minute.
